(19) United States
(12) Patent Application Publication
(10) Pub. No.: US 2006/0179388 A1
(43) Pub. Date: Aug. 10, 2006

(54) Method and apparatus for re-concealing error included in decoded image

(75) Inventor: Byung-sun Choi, Gunpo-si (KR)

Correspondence Address: SUGHRUE MION, PLLC, 2100 PENNSYLVANIA AVENUE, N.W., SUITE 800, WASHINGTON, DC, 20037, US

(73) Assignee: SAMSUNG ELECTRONICS CO., LTD

(21) Appl. No.: 11/271,985

(22) Filed: Nov. 14, 2005

(30) Foreign Application Priority Data
Dec. 31, 2004 (KR) 10-2004-0117934

(51) Int. Cl. H04L 1/00; H03M 13/00; G08C 25/00; G06F 11/00; G06F 11/30

(52) U.S. Cl. 714/746

(57) ABSTRACT

Provided is a method and apparatus for re-concealing an error included in a decoded image. The method includes determining whether a first reference block in a first reference frame, which is used for motion compensation of a current block, includes an error concealed area, and performing error re-concealment on the error concealed area included in the current block if the first reference block includes the error concealed area.

### BACKGROUND OF THE INVENTION

This application claims the priority of Korean Patent Application No. 10-2004-0117934, filed on Dec. 31, 2004, in the Korean Intellectual Property Office, the disclosure of which is incorporated herein in its entirety by reference.

1. Field of the Invention

The present invention relates to error re-concealment, and more particularly, to a method and apparatus for re-concealing an error of an error concealed area included in a current block when the current block is motion-compensated using a reference block including an error concealed area.

2. Description of the Related Art

Since video contains a large amount of data, data compression is required for the storage or transmission of video data. MPEG-1, MPEG-2, MPEG-4, H.261, and H.264 are various international standards for data compression. Video and audio data compressed in accordance with a data compression standard such as MPEG are multiplexed, and stored in the form of a bitstream in a storage medium such as an optical disc or transmitted to a decoder through a communication network. Errors may occur in the storage or transmission. Various techniques exist to conceal errors in images in a moving image decoder.

Such techniques can be roughly divided into error concealment in the spatial domain and error concealment in the temporal domain. Error concealment in the spatial domain involves predicting the image of an error area using video information of the adjacent areas which are decompressed without error. At this time, various prediction methods can be used. Error concealment in the temporal domain involves predicting the image of an error area of a current frame using a previous frame which is decompressed without error. At this time, the area of the previous frame to be used for the prediction is determined using a motion vector of an area adjacent to the error area which is decompressed without error.

Even when using these error concealment techniques, it is difficult to accurately recover a corrupted image. In addition, once one image frame has an error concealed area, it is inevitable that the error-concealed area or a part of it propagates into other frames. FIG. 1 is a view for explaining error propagation in conventional error concealment. Referring to FIG. 1, a reference block 10 indicated by a motion vector of a current block 20 included in a current frame 2 is obtained from a previous frame 1, to perform motion compensation on the current block 20. At this time, since the previous frame 1 includes an error concealed area 13, and the reference block 10 includes a part of the error concealed area 13, the current block 20 also includes an error concealed area 23. In other words, when an error-concealed previous frame is used as a reference frame for motion compensation of a current block, error propagation through frames is inevitable.

### SUMMARY OF THE INVENTION

The present invention provides a method for re-concealing an error, in which the final output video quality of a moving image decoder can be improved, by minimizing error propagation through frames when an error concealed previous frame is used as a reference frame for motion compensation of a current block.

The present invention also provides an apparatus for re-concealing an error, which improves the final output video quality of a moving image decoder, by minimizing error propagation through frames when an error concealed previous frame is used as a reference frame for motion compensation of a current block.

The present invention also provides a computer readable recording medium having recorded thereon a program for implementing a method for re-concealing an error, in which the final output video quality of a moving image decoder can be improved, by minimizing error propagation through frames when an error concealed previous frame is used as a reference frame for motion compensation of a current block.

According to one aspect of the present invention, there is provided a method for re-concealing an error included in a decoded image. The method comprises (a) determining whether a first reference block in a first reference frame, which is used for motion compensation of a current block, includes an error concealed area, and (b) performing error re-concealment on the error concealed area included in the current block if the first reference block includes the error concealed area.

According to another aspect of the present invention, there is provided an apparatus for re-concealing an error included in a decoded image. The apparatus comprises a memory which stores a plurality of reference frames, and an error concealing unit which reads a first reference frame used for motion compensation of a current block from the memory and performs error re-concealment on an error concealed area included in the current block if a first reference block in the first reference frame includes an error concealed area.

According to still another aspect of the present invention, there is provided a computer-readable recording medium having recorded thereon a program for implementing a method for re-concealing an error included in a decoded image. The method comprises (a) determining whether a first reference block in a first reference frame, which is used for motion compensation of a current block, includes an error concealed area, and (b) performing error re-concealment on the error concealed area included in the current block if the first reference block includes the error concealed area.

### BRIEF DESCRIPTION OF THE DRAWINGS

The above and other features and advantages of the present invention will become more apparent by describing in detail an exemplary embodiment thereof with reference to the attached drawings in which:

FIG. 1 is a view for explaining error propagation in conventional error concealment;

FIG. 2 is a block diagram of an error re-concealing apparatus according to an embodiment of the present invention;

FIG. 3 is a block diagram of an example of a moving image decoder including an error re-concealing apparatus according to an embodiment of the present invention;

FIG. 4 is a flowchart illustrating an error re-concealing method according to an embodiment of the present invention;

FIG. 5 illustrates a reference frame and a reference block that are used for motion compensation of a current block;

FIG. 6 illustrates a current block that is divided into an error concealed area and the other areas;

FIG. 7 is a view for explaining a process of re-referring to a frame that is referred to by a reference frame of a current block to re-conceal an error of an error concealed area of the current block;

FIG. 8 illustrates a current block and a plurality of blocks that are adjacent to the current block; and

FIGS. 9A through 9C show cases where an area for sum of absolute difference (SAD) calculation is extended to neighboring areas to re-conceal the error of an error concealed area of a current block.

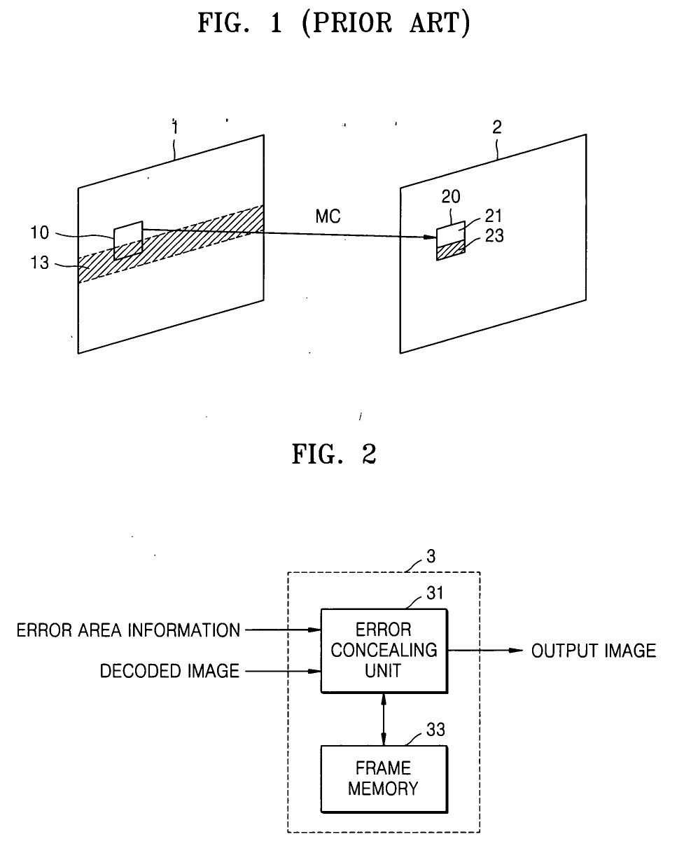

### DETAILED DESCRIPTION OF THE INVENTION

Preferred embodiments of the present invention will now be described in detail with reference to the annexed drawings. In the drawings, the same or similar elements are denoted by the same reference numerals. In the following description, known functions and configurations have not been described in detail, for the sake of brevity.

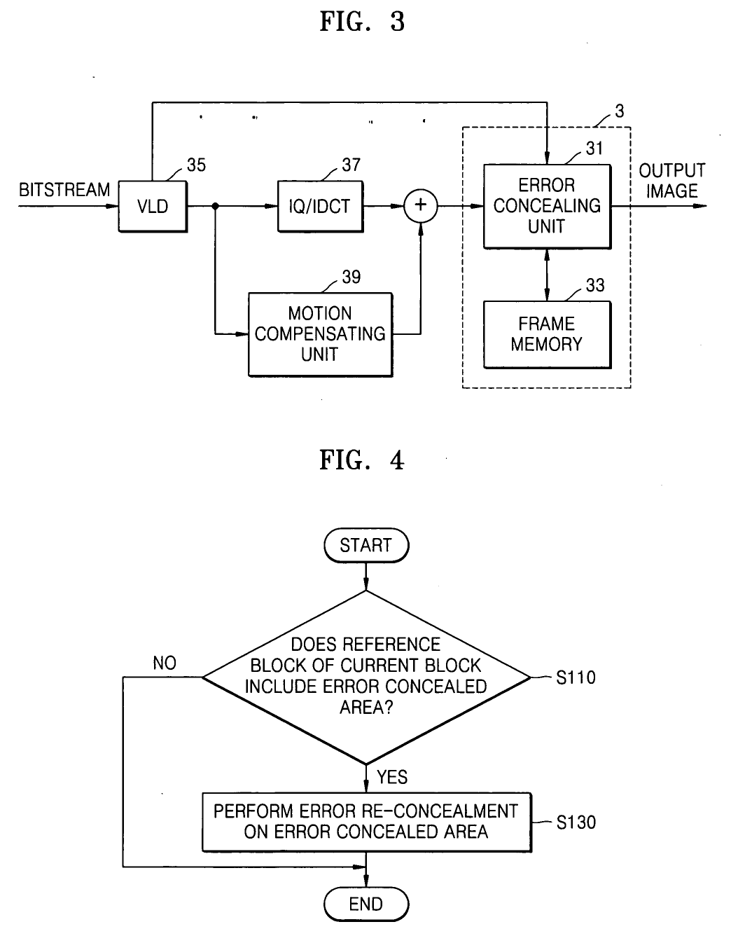

FIG. 2 is a block diagram of an error re-concealing apparatus 3 according to an embodiment of the present invention. Referring to FIG. 2, the error re-concealing apparatus 3 includes an error concealing unit 31 and a frame memory 33. The frame memory 33 stores a plurality of decoded reference frames. The error concealing unit 31 performs error re-concealment according to the present invention using the plurality of decoded reference frames stored in the frame memory 33. Error area information and a decoded current frame are input to the error concealing unit 31. The error area information indicates an area where a transmission error occurs. As shown in FIG. 3, a variable length decoder (VLD) 35 detects an error area and provides information about the error area and information required for error concealment, to the error concealing unit 31. If a first reference block in a first reference frame, which is used for motion compensation of a current block, includes an error concealed area, the error concealing unit 31 re-conceals an error of the error concealed area included in the current block. The first reference frame is stored in the frame memory 33.

FIG. 3 is a block diagram of an example of a moving image decoder including the error re-concealing apparatus 3 according to an embodiment of the present invention. Referring to FIG. 3, the moving image decoder includes the VLD 35, an inverse quantization/inverse discrete cosine transform (IQ/IDCT) unit 37, a motion compensating unit 39, and the error re-concealing apparatus 3. The VLD 35 receives a bitstream and performs variable length decoding on the received bitstream. The IQ/IDCT unit 37 performs IQ and IDCT on received information such as variable length decoded and quantized transform coefficients from the VLD 35. The motion compensating unit 39 is provided with information such as variable length decoded motion vectors from the VLD 35, and performs motion compensation on a current frame in units of a predetermined block size, with reference to the decoded reference frames stored in the memory 33. The error re-concealing apparatus 3 according to an embodiment of the present invention performs not only conventional error concealment, but also error re-concealment on an error concealed area included in a current block, when a reference block used in motion compensation of the current block includes an error concealed area.

An error re-concealing method according to an embodiment of the present invention will be described in detail based on the structure of the error re-concealing apparatus 3 according to an embodiment of the present invention.

FIG. 4 is a flowchart illustrating the error re-concealing method according to an embodiment of the present invention. In the first operation S110, the error concealing unit 31 receives a motion compensated current block and checks if a reference frame that is referred to by the current block includes an error concealed area, or if a reference block of the current block includes an error concealed area. If the reference block of the current block includes an error concealed area, error re-concealment is performed on the error concealed area included in the current block, in operation S130.

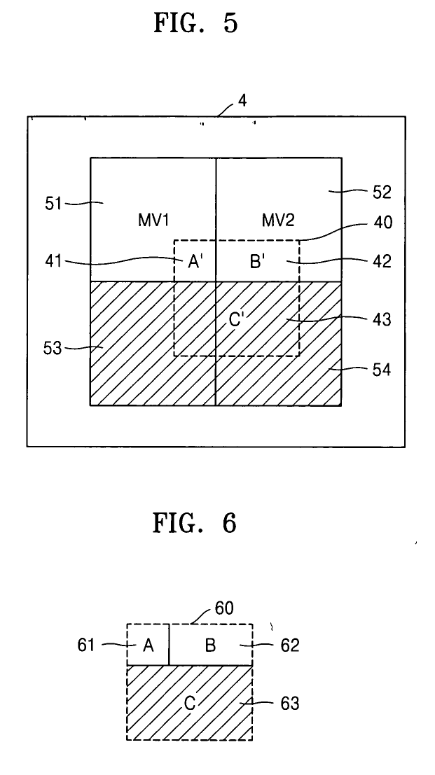

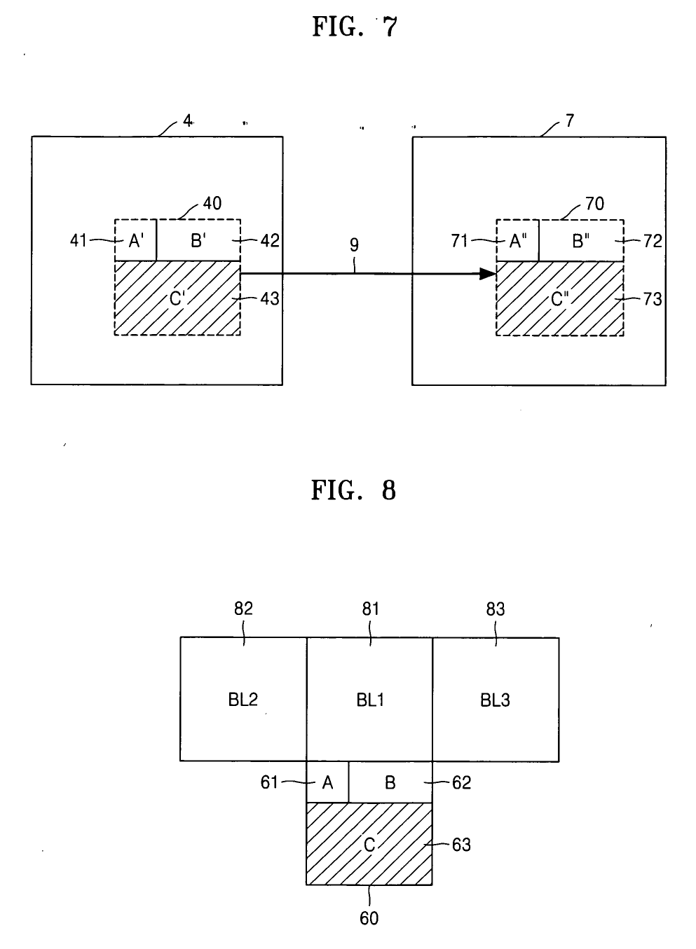

Hereinafter, the error re-concealment in operation S130 will be described in detail with reference to FIGS. 5 through 8 and FIGS. 9A through 9C. FIG. 5 illustrates a reference frame 4 and a reference block 40 that are used for motion compensation of a current block. If the reference frame 4 is split into predetermined sized blocks, e.g., 16×16 blocks, the reference block 40 exists across a first block 51, a second block 52, a third block 53, and a fourth block 54. If the third block 53 and the fourth block 54 are error concealed areas, the reference block 40 is divided into an area A′ 41 included in the first block 51, an area B′ 42 included in the second block 52, and an area C′ 43 included in the third block 53 and the fourth block 54. Since the current block is motion compensated using a reference block indicated by a motion vector of the current block, a current block 60 can also be divided into an area A 61, an area B 62, and an area C 63, as shown in FIG. 6. The area A 61 corresponds to the area A′ 41 of the reference block 40, the area B 62 to the area B′ 42 of the reference block 40, and the area C 63 to the area C′ 43 of the reference block 40.

The present invention involves re-concealing the error concealed area, i.e., the area C 63 of the current block 60. Error re-concealment for the area C 63 is performed by prediction in the temporal domain with re-reference to a frame 7 that is referred to by an error concealing frame, i.e., the reference frame 4, as shown in FIG. 7.

For error re-concealment for the area C 63, a plurality of candidate motion vectors are selected for motion compensation of the reference block 40. In this embodiment, candidate motion vectors are a motion vector MV0 of the current block 60, a motion vector MV1 of the first block 51, and a motion vector MV2 of the second block 52. A block 70 in a re-reference frame 7, which is indicated by a candidate motion vector 9, is divided into an area A″ 71, an area B″ 72, and an area C″ 73. The area A″ 71 corresponds to the area A′ 41 of the reference block 40, the area B″ 72 to the area B′ 42, and the area C″ 73 to the area C′ 43. Matching between the area A″ 71 and the area B″ 72, and between the area A′ 41 and the area B′ 42, is checked using an evaluation function. The evaluation function may be a sum of absolute difference (SAD) function, a sum of absolute transformed difference (SATD) function, a sum of squared difference (SSD) function, or a Lagrangian function. Such a process is performed for each candidate motion vector, and the area C 63 of the current block 60 is substituted for the area C″ 73 of the block 70 that best matches the reference block 40, from among the re-reference blocks indicated by candidate motion vectors. At this time, the block (70) that best matches the reference block 40 may be found not only in locations indicated by candidate motion vectors, but also within a predetermined range around these locations. Also, when the SAD function is used as the evaluation function, error re-concealment may not be performed if the minimum SAD is larger than a predetermined threshold value.

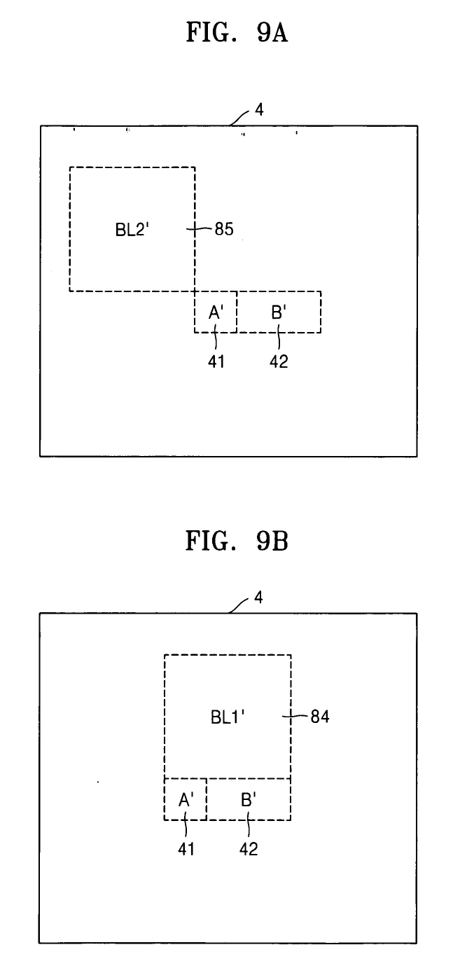

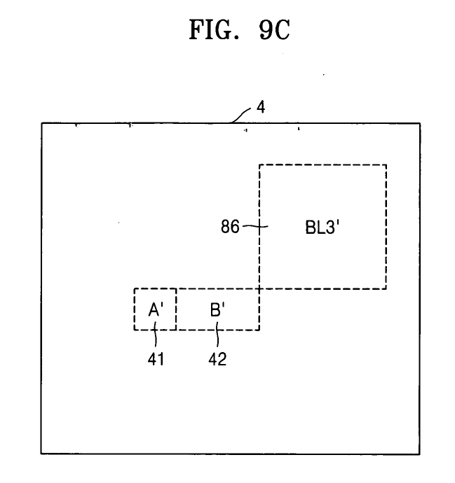

In calculation of an SAD for re-reference, if the sizes of the area A′ 41 and the area B′ 42 are smaller than the area C′ 43, the reliability of the calculated SAD decreases. In this embodiment, when the size of the area C′ 43 is S1 and the sizes of the area A′ 41 and the area B′ 42 are S2, if S2/S1 is larger than a predetermined threshold value R1, error re-concealment is performed. (S2=area(A′)+area(B′), or S2=area(A′)=area(B′)? It isn't clear.) However, if S2/S1 is smaller than a threshold value R2, error re-concealment for the area C 63 is not performed. If S2/S1 is smaller than R1 and larger than R2, error re-concealment is performed after the reliability of an SAD is improved by expanding the area for calculation of the SAD to neighboring areas, as shown in FIGS. 9A through 9C.

First, as shown in FIG. 8, the similarity between the current block 60 and its neighboring blocks BL1 81, BL2 82, and BL3 83 as shown in FIG. 8 is measured to select a similar block. At this time, there may be no similar block, or at least two blocks may be selected as similar blocks. If there is no similar block, error re-concealment is not performed. The similarity is determined by comparing decoding modes, motion vectors, and pixel values of corresponding blocks.

Next, a block corresponding to the selected similar block is determined in the reference frame 4. Blocks BL1′ 84. BL2′ 85, and BL3′ 86 adjacent to the reference block 40 indicated by the motion vector of the current block 60 correspond to the blocks BL1 81, BL2 82, and BL3 83.

If the block BL1 81 is determined to be a similar block to the current block 60, areas matched with the block BL1′ 84, the area A′ 41, and the area B′ 42 are searched for in the re-reference frame 7 using the SAD function, as shown in FIG. 9B. The area C 63 of the current block 60 is substituted for the area C″ 73 corresponding to the area C′ 43 of the matched area in the re-reference frame 7. At this time, to determine areas matched with the area A′ 41 and the area B′ 42, candidate motion vectors are selected in the same manner as described above. If the block BL2 82 or the block BL3 83 is determined to be a similar block to the current block 60, error re-concealment is performed on the area C 63 of the current block 60, in the same manner as the case where the block BL1 81 is determined to be a similar block to the current block 60.

In general, when an error occurs in video data transmission, error concealment is performed on a frame in which the error occurs in a moving image decoder, thereby improving video quality. However, it is impossible to flawlessly restore an image having no error using error concealment. An error that still remains after such error concealment propagates into the following frames, causing video quality degradation. In the present invention, it is possible to improve the final output video quality of a moving image decoder by re-concealing a concealed error that may propagate into the next frame, even after error concealment is performed on a frame in which an error occurs.

The present invention can also be embodied as computer-readable code on a computer-readable recording medium. The computer-readable recording medium is any data storage device that can store data which can be thereafter read by a computer system. Examples of the computer-readable recording medium include read-only memory (ROM), random-access memory (RAM), CD-ROMs, magnetic tapes, floppy disks, optical data storage devices, and carrier waves. The computer-readable recording medium can also be distributed over network coupled computer systems so that the computer-readable code is stored and executed in a distributed fashion.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A method for re-concealing an error included in a decoded image, the method comprising:
(a) determining whether a first reference block in a first reference frame, which is used for motion compensation of a current block, includes an error concealed area; and
(b) performing error re-concealment on the error concealed area included in the current block, if the first reference block includes the error concealed area.

2. The method of claim 1, wherein (b) comprises:
(b1) determining a plurality of candidate motion vectors for motion compensation of the first reference block;
(b2) extracting areas corresponding to remaining areas of the first reference block other than the error concealed area, from reference blocks indicated by the plurality of candidate motion vectors in a second reference frame;
(b3) determining areas that match the remaining areas of the first reference block other than the error concealed area, among the areas extracted from the second reference frame, and determining a second reference block that includes the matched area and is included in the second reference frame; and
(b4) substituting an area of the second reference block corresponding to the error concealed area of the first reference block for the error concealed area included in the current block, to perform error re-concealment.

3. The method of claim 2, wherein the plurality of candidate motion vectors is the motion vector of the current block and the motion vector of at least one of the blocks of the first reference frame and the blocks including the remaining areas of the first reference block other than the error concealed area.

4. The method of claim 2, wherein (b3) is performed using one of a sum of absolute difference (SAD) function, a sum of absolute transformed difference (SATD) function, a sum of squared difference (SSD) function, and a Lagrangian function.

5. The method of claim 2, wherein (b2) comprises determining the reference blocks in the second reference frame in a predetermined range around pixels indicated by the plurality of candidate motion vectors, and extracting the areas corresponding to the remaining areas of the first reference block other than the error concealed area, from the reference blocks.

6. The method of claim 4, wherein if the result of calculation using one of the SAD function, the SATD function, the SSD function, and the Lagrangian function is larger than a predetermined threshold value, error re-concealment is not performed.

7. The method of claim 2, further comprising (c) obtaining the ratio of the size of the remaining areas of the first reference block other than the error concealed area, to the error concealed area,
wherein if the obtained ratio is smaller than a predetermined threshold value, (b) is not performed.

8. An apparatus for re-concealing an error included in a decoded image, the apparatus comprising:
a memory which stores a plurality of reference frames; and
an error concealing unit which reads a first reference frame used for motion compensation of a current block from the memory, and performs error re-concealment on an error concealed area included in the current block if a first reference block in the first reference frame includes an error concealed area.

9. The apparatus of claim 8, wherein the error concealing unit determines a plurality of candidate motion vectors for motion compensation of the first reference block, extracts areas corresponding to remaining areas of the first reference block other than the error concealed area, from reference blocks indicated by the plurality of candidate motion vectors in a second reference frame, determines areas that match the remaining areas of the first reference block other than the error concealed area, from among the areas extracted from the second reference frame and a second reference block that includes the matched area and is included in the second reference frame, and substitutes an area of the second reference block corresponding to the error concealed area of the first reference block for the error concealed area included in the current block, thereby performing error re-concealment.

10. The apparatus of claim 9, wherein the plurality of candidate motion vectors is the motion vector of the current block and the motion vector of at least one of the blocks of the first reference frame and the blocks including the remaining areas of the first reference block other than the error concealed area.

11. The apparatus of claim 9, wherein the error concealing unit uses one of a sum of absolute difference (SAD) function, a sum of absolute transformed difference (SATD) function, a sum of squared difference (SSD) function, and a Lagrangian function, when determining the areas that match the remaining areas of the first reference block other than the error concealed area, from among the areas extracted from the second reference.

12. The apparatus of claim 9, wherein the error concealing unit determines the reference blocks in the second reference frame in a predetermined range around pixels indicated by the plurality of candidate motion vectors, and extracts the areas corresponding to the areas of the first reference block other than the error concealed area from the reference blocks.

13. The apparatus of claim 11, wherein the error concealing unit does not perform error re-concealment if the result of calculation using one of the SAD function, the SATD function, the SSD function, and the Lagrangian function is larger than a predetermined threshold value.

14. The apparatus of claim 9, wherein the error concealing unit obtains the ratio of the size of the remaining areas of the first reference block other than the error concealed area, to the error concealed area,
wherein if the obtained ratio is smaller than a predetermined threshold value, error re-concealment is not performed.

15. A computer-readable recording medium having recorded thereon a program for implementing a method for re-concealing an error included in a decoded image, the method comprising:
(a) determining whether a first reference block in a first reference frame, which is used for motion compensation of a current block, includes an error concealed area; and
(b) performing error re-concealment on the error concealed area included in the current block, if the first reference block includes the error concealed area.

16. The computer-readable recording medium of claim 15, wherein
(b) comprises:
(b1) determining a plurality of candidate motion vectors for motion compensation of the first reference block;
(b2) extracting areas corresponding to remaining areas of the first reference block other than the error concealed area, from reference blocks indicated by the plurality of candidate motion vectors in a second reference frame;
(b3) determining areas that match the remaining areas of the first reference block other than the error concealed area, among the areas extracted from the second reference frame, and determining a second reference block that includes the matched area and is included in the second reference frame; and
(b4) substituting an area of the second reference block corresponding to the error concealed area of the first reference block for the error concealed area included in the current block, to perform error re-concealment.

17. The computer-readable recording medium of claim 16, wherein the plurality of candidate motion vectors is the motion vector of the current block and the motion vector of at least one of the blocks of the first reference frame, and the blocks including the remaining areas of the first reference block other than the error concealed area.

18. The computer-readable recording medium of claim 16, wherein (b3) is performed using one of a sum of absolute difference (SAD) function, a sum of absolute transformed difference (SATD) function, a sum of squared difference (SSD) function, and a Lagrangian function.

19. The computer-readable recording medium of claim 16, wherein (b2) comprises determining the reference blocks in the second reference frame in a predetermined range around pixels indicated by the plurality of candidate motion vectors, and extracting the areas corresponding to the remaining areas of the first reference block other than the error concealed area, from the reference blocks.

20. The computer-readable recording medium of claim 18, wherein if the result of calculation using one of the SAD function, the SATD function, the SSD function, and the Lagrangian function is larger than a predetermined threshold value, error re-concealment is not performed.

21. The computer-readable recording medium of claim 16, further comprising (c) obtaining the ratio of the size of the remaining areas of the first reference block other than the error concealed area, to the error concealed area,
wherein if the obtained ratio is smaller than a predetermined threshold value, error re-concealment is not performed.
